(19) United States
(12) Patent Application Publication
(10) Pub. No.: US 2024/0260355 A1
(43) Pub. Date: Aug. 1, 2024

(54) Light Emitting Display Device

(71) Applicant: LG Display Co., Ltd., Seoul (KR)

(72) Inventors: Chang Hwan KWAK, Paju-si (KR); Yun Hee CHOI, Paju-si (KR); Sun Kap KWON, Paju-si (KR); Jin Ho PARK, Paju-si (KR)

(73) Assignee: LG Display Co., Ltd., Seoul (KR)

(21) Appl. No.: 18/475,773

(22) Filed: Sep. 27, 2023

(30) Foreign Application Priority Data
Jan. 30, 2023 (KR) 10-2023-0012203

(51) Int. Cl. H10K 59/131

(52) U.S. Cl. CPC H10K 59/131

(57) ABSTRACT

A light emitting display device includes a substrate including a display area including a plurality of sub-pixels and a non-display area surrounding the display area, a plurality of first electrodes provided in the plurality of sub-pixels, a second electrode facing the plurality of first electrodes and extending over the entire display area and a part of the non-display area, an interlayer including a plurality of stacks provided between the plurality of first electrodes and the second electrode and a charge generation layer between the plurality of stacks, a first connection electrode provided in the non-display area and connected to the second electrode, and a second connection electrode disposed closer to the display area than the first connection electrode and connected to the charge generation layer, thus stabilizing the potential of a common layer having high mobility by using a connection electrode to prevent lateral leakage current caused by the common layer.

### CROSS-REFERENCE TO RELATED APPLICATION

This application claims the priority of Korean Patent Application No. 10-2023-0012203, filed on Jan. 30, 2023, which is hereby incorporated by reference in its entirety.

### BACKGROUND

### Field of the Disclosure

The present disclosure relates to a display device, and more particularly, to a light emitting display device capable of stabilizing the potential of a common layer having high mobility to prevent lateral leakage current caused by the common layer by including a connection electrode connected to the common layer, and preventing outside air and moisture permeation in the edge area by metal components of the common layer.

### Description of the Background

With the development of the information society, demand for display devices for displaying images in various forms is increasing.

A light emitting display device in which pixels are composed of light emitting elements does not require a separate light source and thus is advantageous in achieving a slim or flexible configuration, and has a high color purity.

The light emitting display device may include a plurality of common layers together with an emission layer to increase light emission efficiency.

Since the plurality of common layers is commonly provided in sub-pixels and includes a material with high mobility, lateral leakage current caused by the material may be generated.

When lateral leakage current is generated, a turned-off sub-pixel adjacent to a turned-on sub-pixel operates according to application of a voltage to the turned-on sub-pixel, causing leakage of emitted light.

### SUMMARY

Accordingly, the present disclosure is directed to a light emitting display device that substantially obviates one or more problems due to limitations and disadvantages described above.

More specifically, the present disclosure is to provide a light emitting display device having a reset electrode through which a reset voltage for resetting the potential of a common layer having high mobility is supplied to prevent problems caused by lateral leakage current.

The light emitting display device of the present disclosure includes a connection electrode connected to a common layer having high mobility to stabilize the potential of the common layer and prevent lateral leakage current caused by the common layer.

In addition, the connection electrode is provided in a non-display area, and outside air and moisture permeation is prevented in the edge area by metal components of the common layer.

Additional advantages and features of the disclosure will be set forth in part in the description which follows and in part will become apparent to those having ordinary skill in the art upon examination of the following or may be learned from practice of the disclosure. Other advantages of the disclosure may be realized and attained by the structure particularly pointed out in the written description and claims hereof as well as the appended drawings.

To achieve these and other advantages and in accordance with the disclosure, as embodied and broadly described herein, a light emitting display device includes a substrate including a display area including a plurality of sub-pixels and a non-display area surrounding the display area, a plurality of first electrodes provided in the plurality of sub-pixels, a second electrode facing the plurality of first electrodes and extending over the entire display area and a part of the non-display area, an interlayer including a plurality of stacks provided between the plurality of first electrodes and the second electrode and a charge generation layer between the plurality of stacks, a first connection electrode provided in the non-display area and connected to the second electrode, and a second connection electrode disposed closer to the display area than the first connection electrode and connected to the charge generation layer.

In another aspect of the present disclosure, a light emitting display device includes a substrate including a display area having a plurality of sub-pixels and a non-display area surrounding the display area; a plurality of first electrodes disposed at the plurality of sub-pixels; a first stack including a first common layer, a first emission layer, and a second common layer on the plurality of first electrodes; a third common layer disposed on the first stack; a second stack including a fourth common layer, a second emission layer, and a fifth common layer on the third common layer; a second electrode provided on the second stack over the entire display area and a part of the non-display area; a first connection electrode disposed on a same layer as the plurality of first electrodes at the non-display area and connected to the second electrode; and a second connection electrode disposed on a same layer as the plurality of first electrodes disposed to closer to the display area than the first connection electrode and connected to at least one of the first common layer, the third common layer, and the fourth common layer.

It is to be understood that both the foregoing general description and the following detailed description of the present disclosure are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain the principle of the disclosure.

In the drawings:

FIG. 1 is a schematic block diagram of a light emitting display device according to the present disclosure;

FIG. 2 is a plan view illustrating a light emitting display device according to a first aspect of the present disclosure;

FIG. 3 is a cross-sectional view taken along line I-I′ of FIG. 2;

FIGS. 4A to 4C are cross-sectional views illustrating areas A, B, and C of FIG. 3;

FIG. 5 is a circuit diagram illustrating an equivalent circuit of light emitting elements of adjacent sub-pixels in the light emitting display device according to an aspect of the present disclosure;

FIG. 6 is a timing diagram showing voltage changes at first nodes and second nodes of adjacent sub-pixels in the light emitting display device according to an aspect of the present disclosure;

FIGS. 7A to 7F are cross-sectional views illustrating a method of manufacturing the light emitting display device of FIG. 2;

FIG. 8 is a plan view illustrating a light emitting display device according to a second aspect of the present disclosure;

FIG. 9 is a plan view illustrating a light emitting display device according to a third aspect of the present disclosure;

FIG. 10 is a plan view illustrating a light emitting display device according to a fourth aspect of the present disclosure;

FIG. 11 is a cross-sectional view taken along line II-II′ of FIG. 10;

FIG. 12 is a cross-sectional view illustrating a method of exposing a common layer connection electrode in the light emitting display device according to the fourth aspect; and

FIG. 13 is a cross-sectional view of a light emitting display device according to a fifth aspect of the present disclosure.

### DETAILED DESCRIPTION

Reference will now be made in detail to the various aspects of the present disclosure, examples of which are illustrated in the accompanying drawings. Wherever possible, the same reference numbers will be used throughout the drawings to refer to the same or like parts. In the following description of the present disclosure, detailed descriptions of known functions and configurations incorporated herein will be omitted when the same may obscure the subject matter of the present disclosure. In addition, the names of elements used in the following description are selected in consideration of clear description of the specification, and may differ from the names of elements of actual products.

The shape, size, ratio, angle, number, and the like shown in the drawings to illustrate various aspects of the present disclosure are merely provided for illustration, and are not limited to the content shown in the drawings. Wherever possible, the same reference numbers will be used throughout the drawings to refer to the same or like parts. In the following description, detailed descriptions of technologies or configurations related to the present disclosure may be omitted to avoid unnecessarily obscuring the subject matter of the present disclosure. When terms such as “including”, “having”, and “comprising” are used throughout the specification, an additional component may be present, unless “only” is used. A component described in a singular form encompasses a plurality thereof unless particularly stated otherwise.

The components included in the aspects of the present disclosure should be interpreted to include an error range, even if there is no additional particular description thereof.

In describing a variety of aspects of the present disclosure, when terms for positional relationships such as “on”, “above”, “under” and “next to” are used, at least one intervening element may be present between two elements, unless “immediately” or “directly” is used.

In describing a variety of aspects of the present disclosure, when terms related to temporal relationships, such as “after”, “subsequently”, “next” and “before”, are used, the non-continuous case may be included, unless “immediately” or “directly” is used.

In describing a variety of aspects of the present disclosure, terms such as “first” and “second” may be used to describe a variety of components, but these terms only aim to distinguish the same or similar components from one another. Accordingly, throughout the specification, a “first” component may be the same as a “second” component within the technical concept of the present disclosure, unless specifically mentioned otherwise.

Features of various aspects of the present disclosure may be partially or completely coupled to or combined with each other, and may be variously inter-operated with each other and driven technically. The aspects of the present disclosure may be carried out independently from each other, or may be carried out together in an interrelated manner.

Hereinafter, a light emitting display device of the present disclosure will be described with reference to the drawings.

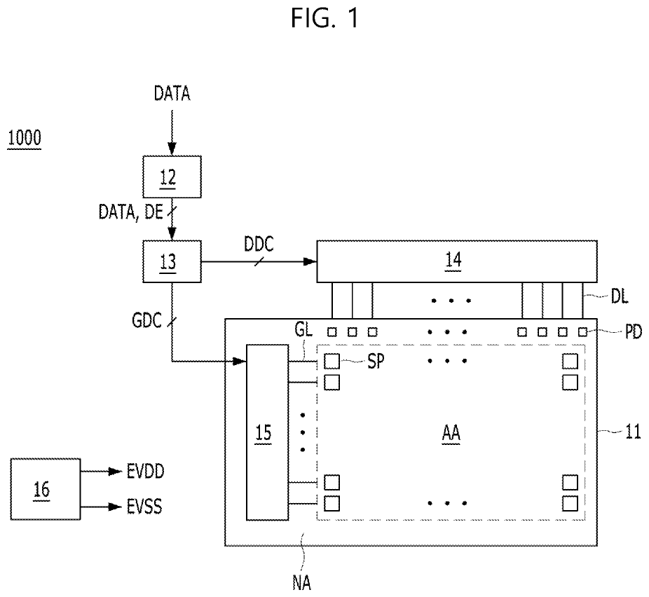

FIG. 1 is a schematic block diagram of a light emitting display device according to an aspect of the present disclosure.

As illustrated in FIG. 1, the light emitting display device 1000 according to an aspect of the present disclosure may include a display panel 11, an image processor 12, a timing controller 13, a data driver 14, a scan driver 15, and a power supply 16.

The display panel 11 may display an image in response to a data signal DATA supplied from the data driver 14, a scan signal supplied from the scan driver 15, and power supplied from the power supply 16.

The display panel 11 may include sub-pixels SP disposed at intersections of a plurality of gate lines GL and a plurality of data lines DL. The structure of the sub-pixels SP may be changed in various manners according to the type of the display device 1000.

For example, the sub-pixels SP may be formed in a top emission structure, a bottom emission structure, or a dual emission structure. The sub-pixels SP refer to units capable of emitting lights of respective colors with or without a specific type of color filter. For example, the sub-pixels SP may include a red sub-pixel, a green sub-pixel, and a blue sub-pixel. Alternatively, the sub-pixels SP may include, for example, a red sub-pixel, a blue sub-pixel, a white sub-pixel, and a green sub-pixel. The sub-pixels SP may have one or more different emission areas according to light emitting characteristics. For example, a blue sub-pixel and sub-pixels emitting different colors may have different emission areas.

One or more sub-pixels SP may constitute one unit pixel. For example, one unit pixel may include red, green, and blue sub-pixels, and the red, green, and blue sub-pixels may be repeatedly disposed. Alternatively, one unit pixel may include red, green, blue, and white sub-pixels, and the red, green, blue, and white sub-pixels may be repeatedly arranged or may be disposed in a quad type. In an aspect according to the present disclosure, the sub-pixels may have various color types, arrangement types, and arrangement orders according to light emitting characteristics, device lifespan, and device specifications, but the present disclosure is not limited thereto.

The display panel 11 may be divided into a display area AA in which sub-pixels SP are disposed to display an image, and a non-display area NA around the display area AA. The scan driver 15 may be provided in the non-display area NA of the display panel 11. In addition, the non-display area NA may include a pad portion PAD including pad electrodes PD.

The image processor 12 may output a data enable signal DE and the like along with an externally supplied data signal DATA. The image processor 12 may output one or more of a vertical synchronization signal, a horizontal synchronization signal, and a clock signal in addition to the data enable signal DE, but illustration of these signals is omitted for convenience of description.

The timing controller 13 may receive the data signal DATA along with driving signals from the image processor 12. The driving signals may include the data enable signal DE. Alternatively, the driving signals may include the vertical synchronization signal, the horizontal synchronization signal, and the clock signal. The timing controller 13 may output a data timing control signal DDC for controlling operation timing of the data driver 14 and a gate timing control signal GDC for controlling operation timing of the scan driver 15 on the basis of the driving signals.

The data driver 14 may sample and latch the data signal DATA supplied from the timing controller 13 in response to the data timing control signal DDC supplied from the timing controller 13, convert the same into a gamma reference voltage, and outputs the gamma reference voltage.

The data driver 14 may output the data signal DATA through the data lines DL. The data driver 14 may be implemented in the form of an integrated circuit (IC). For example, the data driver 14 may be electrically connected to the pad electrodes PD disposed in the non-display area NA of the display panel 11 through a flexible circuit film (not shown).

The scan driver 15 may output a scan signal in response to the gate timing control signal GDC supplied from the timing controller 13. The scan driver 15 may output the scan signal through the gate lines GL. The scan driver 15 may be implemented in the form of an integrated circuit (IC) or implemented in the display panel 11 in a gate-in-panel (GIP) structure.

The power supply 16 may output a high-potential voltage and a low-potential voltage for driving the display panel 11. The power supply 16 may supply the high-potential voltage to the display panel 11 through a first power line EVDD (driving power line or pixel power line), and may supply the low-potential voltage to the display panel 11 through a second power line EVSS (auxiliary power line or common power line).

The display panel 11 is divided into the display area AA and the non-display area NA, and may include a plurality of sub-pixels SP defined by gate lines GL and data lines DL intersecting each other in a matrix form in the display area AA.

The sub-pixels SP may include sub-pixels emitting at least two of red light, green light, blue light, yellow light, magenta light, and cyan light. In addition, the plurality of sub-pixels SP may emit respective colors with or without a specific type of color filter. However, the present disclosure is not necessarily limited thereto, and the sub-pixels SP may have various color types, arrangement types, and arrangement orders according to light emitting characteristics, device lifespan, and device specifications, etc.

Hereinafter, light emitting display devices according to aspects of the present disclosure will be described.

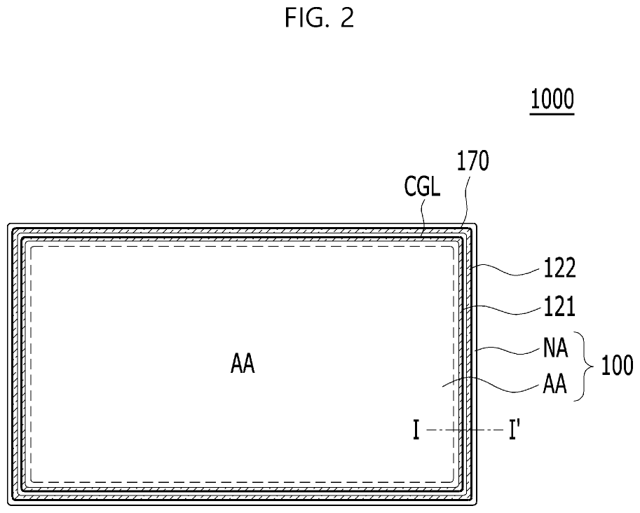

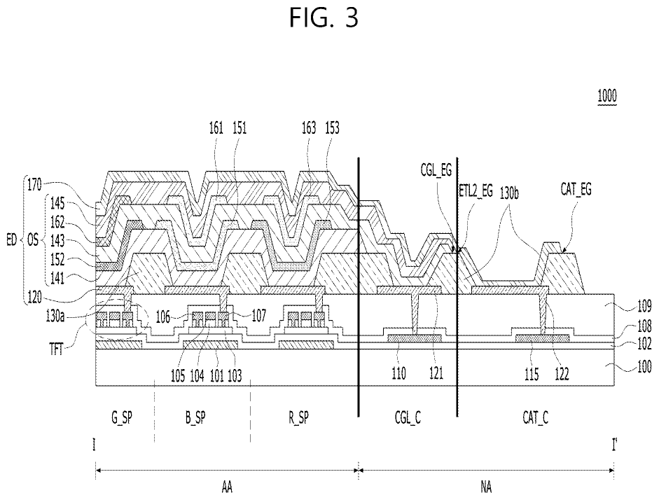

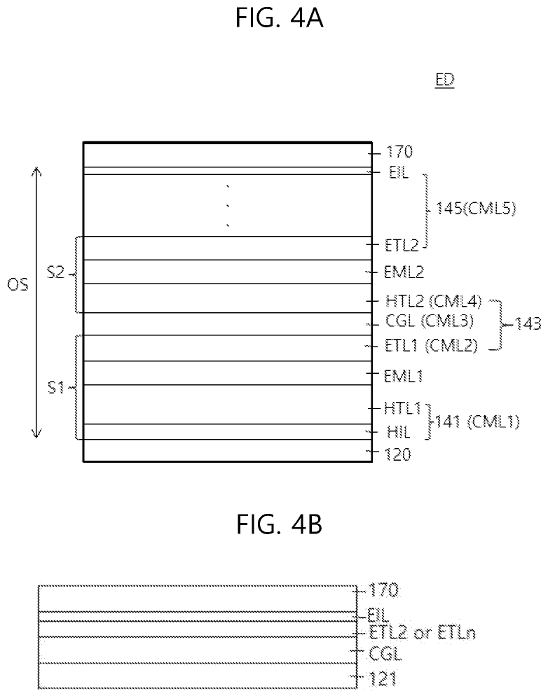

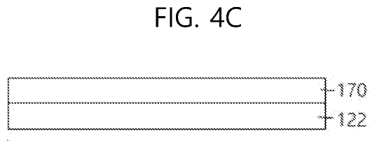

FIG. 2 is a plan view illustrating a light emitting display device according to a first aspect of the present disclosure. FIG. 3 is a cross-sectional view taken along line I-I′ of FIG. 2. FIGS. 4A to 4C are cross-sectional views illustrating areas A, B, and C of FIG. 3.

As illustrated in FIGS. 2 and 3, the light emitting display device 1000 according to the first aspect of the present disclosure includes a substrate 100 including a display area AA in which a plurality of sub-pixels G_SP, B_SP, and R_SP is disposed and a non-display area NA surrounding the display area AA, a plurality of first electrodes 120 respectively provided in the plurality of sub-pixels G_SP, B_SP, and R_SP, a second electrode 170 facing the plurality of first electrodes 120 and extending over the entire display area AA and a part of the non-display area NA, an interlayer OS provided between the plurality of first electrodes 120 and the second electrode 170, a first connection electrode 122 provided in the non-display area NA and connected to the second electrode 170, and a second connection electrode 121 provided inside the first connection electrode 122 and connected to a common layer having high mobility (internal layer 143 in FIG. 3).

Here, the interlayer OS includes a plurality of stacks S1, S2, . . . , and a charge generation layer CGL provided between adjacent stacks, as illustrated in FIG. 4A. For example, if n stacks (where n being a natural number equal to or greater than 2) are provided, n−1 charge generation layers CGLs may be provided. In addition, the charge generation layer CGL may include an n-type charge generation layer nCGL generating electrons and supplying the same to an adjacent lower stack and a p-type charge generation layer pCGL generating holes and supplying the same to an adjacent upper stack. In some cases, the n-type charge generation layer nCGL and the p-type charge generation layer may be formed as one layer without distinguishing a boundary from each other.

The n-type charge generation layer nCGL may further include metal ions as an n-type dopant to smoothly supply electrons in a vertical direction along with a host. These metal ions may include alkali metals such as lithium (Li), alkaline earth metals such as calcium (Ca) and strontium (Sr), or lanthanides such as ytterbium (Yb). However, since metal ions have high electrical mobility in the horizontal direction as well as in the vertical direction, if the charge generation layer is commonly formed in the display area AA, leakage current may be transmitted between adjacent sub-pixels through the charge generation layer.

Light emitting elements GED, BED, and RED formed by laminating the first electrode 120, the interlayer OS, and the second electrode 170 are respectively formed in the sub-pixels G_SP, B_SP, and R_SP in the display area AA. Here, the first electrode 120 may be divided for each of the sub-pixels G_SP, B_SP, and R_SP, and the second electrode 170 may be continuously formed over the plurality of sub-pixels G_SP, B_SP, and R_SP provided in the display area AA.

As illustrated in FIG. 3, in the light emitting elements GED, BED, and RED, the interlayer OS may include a hole injection and transport layer 141, first emission layers 152, 151, and 153, a charge transport and generation layer 143, second emission layers 162, 161, and 163, and an electron transport and injection layer 145.

The hole injection and transport layer 141, the charge transport and generation layer 143, and the electron transport and injection layer 145 may be formed without being disconnected in at least the display area AA, and portions thereof may extend to the non-display area NA, and thus may be referred to as common layers in that they are commonly formed in the display area AA. The hole injection and transport layer 141, the charge transport and generation layer 143, and the electron transport and injection layer 145 may be formed using, for example, an open mask.

In addition, each of the hole injection and transport layer 141, the charge transport and generation layer 143, and the electron transport and injection layer 145 may be composed of a plurality of layers.

FIG. 4A illustrates a structure of the light emitting element ED of each sub-pixel, in which the first stack S1, the charge generation layer CGL, and the second stack S2 are sequentially provided on the first electrode 120 as the interlayer OS. If the interlayer OS includes three or more stacks, one or more sets each including a charge generation layer and an additional stack may be further provided on the second stack S2.

The first stack S1 includes a hole injection layer HIL, a first hole transport layer HTL1, a first emission layer EML1, and a first electron transport layer ETL1. The second stack S2 on the charge generation layer CGL may include a second hole transport layer HTL2, a second emission layer EML2, and a second electron transport layer ETL2.

Meanwhile, common layers may be classified into common layers of different properties depending on whether they are located on or below an emission layer and whether they are located between stacks to serve as a charge generation layer.

For example, as illustrated in FIG. 3, when it is assumed that the interlayer OS between the first and second electrodes 120 and 170 has a two-stack structure, the hole injection and transport layer 141, the charge transport and generation layer 143, and the electron transport and injection layer 145 may be classified as follows.

The hole injection and transport layer 141 may include, for example, the hole injection layer HIL and the first hole transport layer HTL1, as illustrated in FIG. 4A. The hole injection and transport layer 141 is located below the first emission layer EML1 152, 151, and 153 and is commonly provided in the display area AA in terms of hole injection and generation, and thus the hole injection and transport layer 141 may be referred to as a first common layer CML1.

The charge transport and generation layer 143 may include the first electron transport layer ETL1, the charge generation layer CGL, and the second hole transport layer HTL2. Here, the first electron transport layer ETL1 of the charge transport and generation layer 143 is provided in the first stack S1 and may be referred to as a second common layer CML2, and the charge generation layer CGL is provided between the first and second stacks S1 and S2 and may be referred to as a third common layer CML3. The second hole transport layer HTL2 of the second stack S2 may be referred to as a fourth common layer CML4.

Among the second common layer CML2 serving as the first electron transport layer ETL1, the third common layer CML3 serving as the charge generation layer CGL, and the fourth common layer CML4 serving as the second hole transport layer HTL2 which constitute the charge transport and generation layer 143 illustrated in FIG. 3, only the charge generation layer CGL may be directly connected to the second connection electrode 121 to reduce connection resistance. In this case, the second common layer CML2 serving as the first electron transport layer ETL1 and the fourth common layer CML4 serving as the second hole transport layer HTL2 have edges corresponding to or close to the edge of the hole injection and transport layer 141.

In this case, the electron transport and injection layer 145 includes the second electron transport layer ETL2 and an electron injection layer EIL and is commonly provided in the second stack in terms of electron transport and electron injection, and thus the electron transport and injection layer 145 may be referred to as a fifth common layer CML5.

FIG. 4A shows n stacks as the interlayer OS. When the interlayer OS includes two stacks, the second electron transport layer ETL2 of the electron transport and injection layer 145 may directly contact the electron injection layer EIL under the second electrode 170.

In the light emitting display device according to the first aspect of the present disclosure, as illustrated in FIG. 4B, the second connection electrode 121 may be directly connected to the charge generation layer CGL included in the charge transport and generation layer 143. In some cases, the lower surface of the first electron transport layer ETL1 included in the charge transfer and generation layer 143 may be directly connected to the second connection electrode 121.

The electron transport and injection layer 145 may include the second electron transport layer ETL2 and the electron injection layer EIL.

In the light emitting display device according to the first aspect of the present disclosure, the hole injection and transport layer 141, the charge transport and generation layer 143, and the electron transport and injection layer 145 may be formed using an open mask, these layers may have different edges. In particular, in the light emitting display device of the present disclosure, the charge generation layer CGL included in the charge transport and generation layer 143 is connected to the second connection electrode 121. In addition, the charge generation layer is connected to a reset voltage line 110 under the second connection electrode 121 to receive a reset voltage signal periodically. To this end, the charge generation layer extends over the display area AA and a part of the non-display area NA and overlaps with the second connection electrode 121, and the edge CGL_EG of the charge generation layer CGL may be positioned between the second connection electrode 121 and the first connection electrode 122. Therefore, in the light emitting display device according to the first aspect of the present disclosure, the edge CGL_EG of the charge generation layer CGL may be positioned outside the edge of the hole injection and transport layer 141 having a high resistance to which an electrical signal is not directly applied.

In addition, as illustrated in FIG. 3, since the electron transport and injection layer 145 including the electron injection layer EIL provided directly below the second electrode 170 includes the electron injection layer EIL having a small interfacial resistance with respect to the second electrode 170, the edge ETL2_EG of the electron transport and injection layer 145 may be positioned outside the edge CGL_EG or positioned to correspond to the edge CGL_EG of the charge generation layer. Here, the second electron transport layer ETL2 and the electron injection layer EIL of the electron transport and injection layer 145 are involved in electron transport and electron injection and have relatively low resistance among components included in the interlayer OS, and thus even if they are located on the charge generation layer CGL and the second electrode 170, the resistance may not greatly increase when the charge generation layer CGL and the second electrode 170 are electrically connected. In some cases, the edge of the second electron transport layer may be positioned inside the edge of the electron injection layer, and only the electron injection layer EIL may be positioned between the charge generation layer CGL and the second electrode 170. Alternatively, the edge ETL2_EG of the second electron transport layer ETL2 may correspond to the edge of the charge generation layer CGL or may be positioned slightly outside the edge of the charge generation layer CGL, and the electron injection layer EIL may have the edge corresponding to the edge of the cathode 170 such that the edge of the electron injection layer EIL is positioned outside the edge of the electron transport layer ETL2.

Meanwhile, the electron injection layer EIL includes an inorganic compound such as metal or halogen, and even if the electron injection layer EIL is provided between the charge generation layer CGL and the second electrode 170 at the position where the second connection electrode 121 is located, connection resistance may not increase. Further, the electron injection layer EIL may serve to block outside air or moisture according to a metal or inorganic component contained therein in the non-display area NA.

Here, as illustrated in FIGS. 2 and 3, the first connection electrode 122 is connected to the second electrode 170 positioned at the top of the light emitting element ED, and is positioned outside the first connection electrode 121.

In addition, the edge CAT_EG of the second electrode 170 (cathode) is provided outside the edge CGL_EG of the charge generation layer, and is connected to the second connection electrode 122 as illustrated in FIGS. 3 and 4C. The first connection electrode 122 is connected to a second power line 115 (i.e., an auxiliary power line or a common power line) through which a low-potential voltage VSS is supplied. Accordingly, the second electrode 170 may receive the low-potential voltage VSS through connection of the first connection electrode 122 and the second power line 115.

As illustrated in FIG. 2, the second connection electrode 121 is located in the non-display area NA inside the first connection electrode 122 and may have a closed loop shape. The charge generation layer CGL may extend over the entire display area AA and a part of the non-display area NA and may be formed on the second connection electrode.

As illustrated in FIG. 2, the first connection electrode 122 may also have a closed loop shape. In addition, the second electrode 170 may be formed in the entire display area AA and extend to a part of the non-display area NA to be formed on the first connection electrode 122. Since the first connection electrode 122 is located outside the second connection electrode 121, the second electrode 170 may be formed with a larger area than the charge generation layer CGL and located outside the charge generation layer CGL.

In the light emitting display device of the present disclosure, the first connection electrode 122 and the second connection electrode 121 are not necessarily limited to a closed ring shape. The first connection electrode 122 and the second connection electrode 121 may have a ring shape with an opening which allows the potentials of the second electrode 170 and the charge generation layer CGL to be constant.

Meanwhile, when the second connection electrode 121 has a closed ring shape, connection CGL_C between the charge generation layer CGL and the second connection electrode 121 may be provided in the linear closed ring shape of the second connection electrode 121. Alternatively, when the second connection electrode 121 has a closed ring shape, connection CGL_C between the charge generation layer CGL and the second connection electrode 121 may be provided in a closed ring shape only in a part of the linear closed ring shape. In the latter case, connection CGL_C between the charge generation layer CGL and the second connection electrode 121 may be provided in the shape of a plurality of separated islands on the second connection electrode 121.

Components that have not been described in the light emitting display device of FIG. 3 will be described.

In each of the sub-pixels G_SP, B_SP, and R_SP, the first electrode 120 of the light emitting element ED is connected to a thin film transistor TFT. For example, as illustrated in FIG. 3, the thin film transistor TFT includes a semiconductor layer 103, a gate electrode 105 overlapping with a channel of the semiconductor layer 103 having a gate insulating layer 104 interposed therebetween, a source electrode 106 and a drain electrode 107 connected to the semiconductor layer 103.

The source electrode 106 or the drain electrode 107 of the semiconductor layer 103 may be connected to the first electrode 120 of the light emitting element.

The semiconductor layer 103 may include at least one of an oxide semiconductor, amorphous silicon, and crystalline silicon.

A light shielding layer 101 may be further provided below the semiconductor layer 103 to prevent light coming from the lower side of the substrate 100 from affecting the semiconductor layer 103.

A buffer layer 102 may be further provided between the light shielding layer 101 and the semiconductor layer 103. The buffer layer 102 may be formed on the entire surface of the substrate 100 to prevent impurities in the substrate 100 from penetrating into the upper structure.

An inorganic passivation layer 108 and a planarization layer 109 may be sequentially formed to protect the thin film transistor TFT.

The buffer layer 102 and the inorganic passivation layer 108 may be, for example, any one of a silicon oxide layer, a silicon nitride layer, a silicon oxynitride layer, a metal oxide layer, and a metal nitride layer.

The planarization layer 109 may be formed of at least one of organic materials such as photo acryl, polyimide, a benzocyclobutene resin, and acrylate.

The first connection electrode 122 and the second connection electrode 121 may be formed of the same material on the same layer as the first electrode 120. That is, in the light emitting display device of the present disclosure, the second connection electrode 121 for connection to the charge generation layer CGL may be formed through a process of forming the first electrode 120 without using a separate process. The first connection electrode 122, the second connection electrode 121, and the first electrode 120 may all be positioned on the planarization layer 109.

Meanwhile, as illustrated in FIG. 3, the lower reset voltage line 110 and the second power line 115 may be formed on the same layer as the source electrode 106 and the drain electrode 107 of the thin film transistor, but the present disclosure is not limited thereto. The lower reset voltage line 110 and the second power line 115 may be formed on the same layer as the light shielding layer 101, or the reset voltage line 110 and the second power line 115 may be formed on different layers.

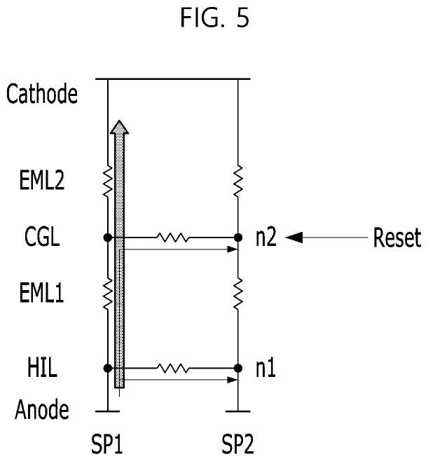

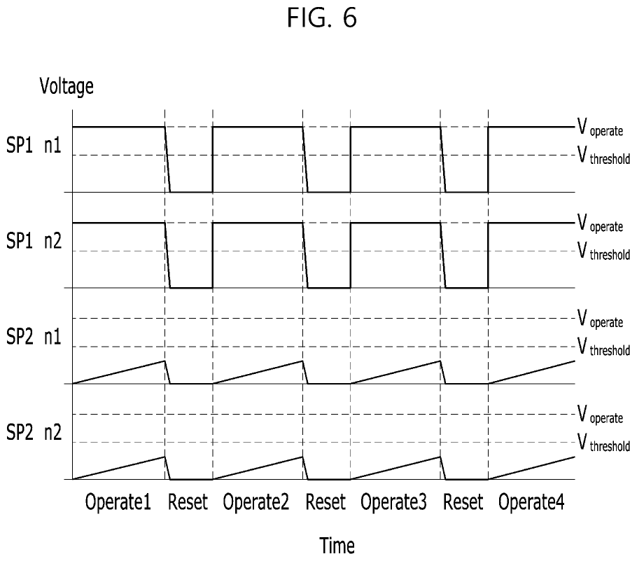

FIG. 5 is a circuit diagram illustrating an equivalent circuit of light emitting elements of adjacent sub-pixels in the light emitting display device according to an aspect of the present disclosure. FIG. 6 is a timing diagram showing voltage changes in first nodes and second nodes of adjacent sub-pixels in the light emitting display device according to an aspect of the present disclosure.

FIG. 5 illustrates that lateral leakage current is generated in the hole injection layer HIL having high mobility and the charge generation layer CGL between adjacent first and second sub-pixels SP1 and SP2 when the first sub-pixel SP1 is turned on and the second sub-pixel SP2 is turned off, and thus when the first sub-pixel SP is selectively turned on, some of the current flowing from the first electrode Anode to the second electrode Cathode flows into a first node n1 where the hole injection layer HIL of the second sub-pixel SP2 is located and a second node n2 where the charge generation layer CGL is located.

In the light emitting display device of the present disclosure, for example, the charge generation layer CGL may be connected to the second connection electrode 121, and a reset signal Reset may be supplied to the second connection electrode 121 to initialize the potential of the second node n2.

Referring to the timing diagram of FIG. 6, when the first sub-pixel SP1 is turned on, a current is generated in the vertical direction from the first electrode Anode to the second electrode Cathode in the first sub-pixel SP1. When the vertical current is generated during operations Operate 1, Operate 2, Operate 3, and Operate 4 of the first sub-pixel SP1 in a turned-on state, the first node n1 of the hole injection layer HIL and the second node n2 of the charge generation layer CGL are synchronized with the signal applied to the first electrode Anode, and have a voltage Voperate equal to or higher than the threshold voltage Vthreshold. It may be ascertained that lateral leakage current is generated at the first node n1 of the hole injection layer HIL and the second node n2 of the charge generation layer CGL in the second sub-pixel SP2 in a turned-off state, and as a result, charges are accumulated and the voltage value increases in the second sub-pixel SP1 during the operations Operate 1, Operate 2, Operate 3, and Operate 4 of the first sub-pixel SP1.

However, in the light emitting display device of the present disclosure, the reset signal Reset may be supplied to the charge generation layer CGL before the voltage of the second sub-pixel SP2 reaches the threshold voltage to initialize the voltage to a reset voltage corresponding to 0 V in a turned-off state or a low-potential voltage at the second node n2. Accordingly, the second node n2 may be initialized with the reset voltage, and the first node n1 connected in series with the second node n2 may also be initialized with the reset voltage. That is, the light emitting display device of the present disclosure includes the charge generation layer CGL commonly provided in the first and second sub-pixels SP1 and SP2, and directly supplies the reset signal to the node where the charge generation layer CGL is positioned to initialize the node even if lateral leakage current is generated, and thus may prevent the second sub-pixel SP2 from operating at a voltage higher than the threshold voltage due to charge accumulation caused by leakage current generated when the adjacent first sub-pixel SP1 operates, preventing color leakage.

Here, the reset voltage Rest may be supplied through the reset voltage line 110 connected to the second connection electrode 121 connected to the charge generation layer CGL in the non-display area NA, as illustrated in FIG. 3.

The light emitting display device of the present disclosure includes the second connection electrode 121 connected to the charge generation layer CGL or the common layer having high mobility, and thus the potential of the charge generation layer CGL or the common layer having high mobility may be periodically reset through the second connection electrode 121. When the potential of the charge generation layer CGL or the common layer having high mobility is reset, charge accumulation in the node of the charge generation layer or the common layer having high mobility due to lateral leakage current may be prevented, and thus light leakage due to light emission of adjacent sub-pixels may be prevented.

In the light emitting display device of the present disclosure, the first and second connection electrodes 122 and 121 may be formed of the same material on the same layer as the first electrode 120 (i.e., anode), thereby ensuring material stability for light emitting elements. Accordingly, it is possible to prevent generation of harmful substances and prevent defects caused thereby. Therefore, it is possible to obtain ESG (environmental social governance) effects in terms of eco-friendliness, low power consumption, and process optimization.

In the light emitting display device of the present disclosure, the charge generation layer CGL or a common layer including metal ions in the organic stacks of the interlayer OS has an edge in the non-display area positioned outside other common layers, and is connected to the second connection electrode 121, and thus outside air or moisture permeation into the display area may be prevented by the metal ions.

Hereinafter, a method of manufacturing the light emitting display device according to an aspect of the present disclosure will be described.

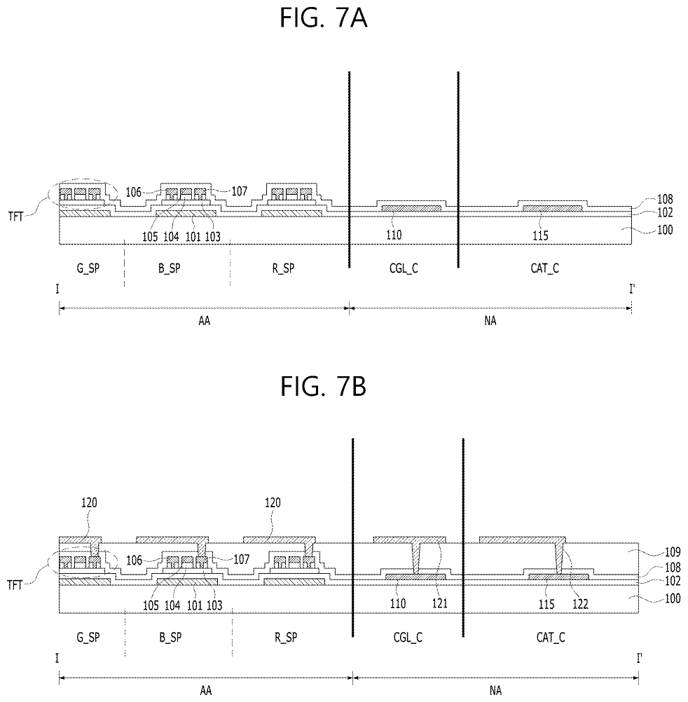

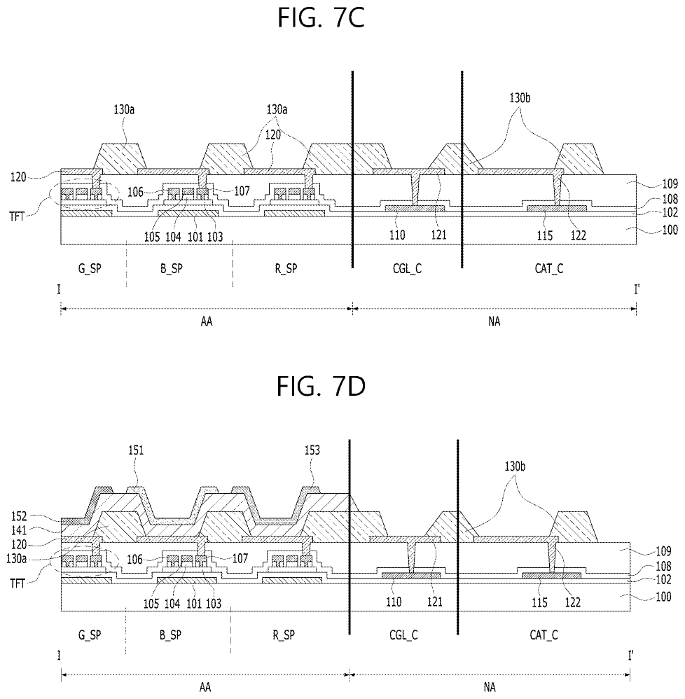

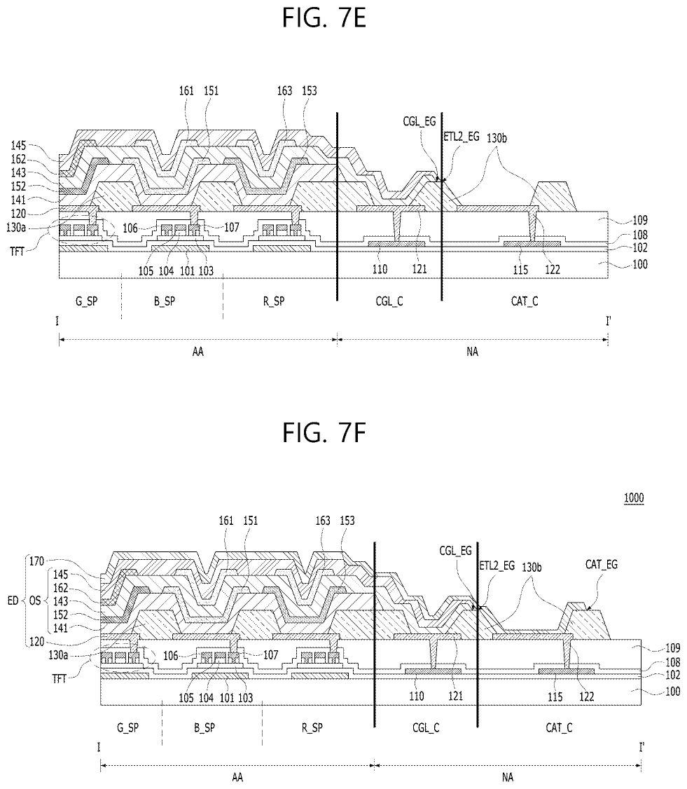

FIGS. 7A to 7F are cross-sectional views illustrating a method of manufacturing the light emitting display device of FIGS. 2 and 3.

As illustrated in FIG. 7A, the light shielding layer 101 is formed on the substrate 100 and the buffer layer 102 covering the light shielding layer 101 is formed thereon.

Subsequently, the semiconductor layer 103 is formed overlapping with the buffer layer 102.

The gate insulating layer 104 is formed on the semiconductor layer 103, and selectively removed to form contact holes through which parts of both sides of the semiconductor layer 103 are exposed.

Subsequently, a metal layer is formed and patterned to form the source electrode 106 and the drain electrode 107 connected to the semiconductor layer 103 through contact holes, and the gate electrode 105 overlapping with the channel of the semiconductor layer 103 with the gate insulating layer 104 interposed therebetween is also formed. In the same process of patterning the metal layer, the reset voltage line 110 and the second power line 115 are formed in the non-display area NA.

Here, the thin film transistor TFT provided in each sub-pixel of the display area NA includes the semiconductor layer 103, the gate electrode 105, the source electrode 107, and the drain electrode 107.

Subsequently, the inorganic passivation layer 108 covering the thin film transistor TFT, the reset voltage line 110, and the second power line 115 is formed.

Subsequently, as illustrated in FIG. 7B, the planarization layer 109 for planarization is formed on the inorganic passivation layer 108.

Subsequently, the planarization layer 109 is selectively patterned to form a contact hole through which a part of the drain electrode 107 of the thin film transistor TFT is exposed, and a contact hole through which the reset voltage line 110 and the second power line 115 are partially exposed.

Subsequently, a first electrode forming material is deposited and selectively removed to form the first electrode 120 connected to the drain electrode 107, the second connection electrode 121 connected to the reset voltage line 110, and the first connection electrode 122 connected to the second power line 115.

Subsequently, as illustrated in FIG. 7C, a first bank 130a covering the edge of the first electrode 120 in the display area AA and defining the light emitting part of the first electrode 120 at exposed portions and a second bank 130b overlapping with the edges of the first connection electrode 122 and the second connection electrode 121 to partially expose the upper surfaces of the first connection electrode 122 and the second connection electrode 121 in the non-display area NA are formed.

Here, the first bank 130a and the second bank 130b may be formed in the same process and integrally formed.

Subsequently, as illustrated in FIG. 7D, the hole injection and transport layer 141 is formed in the display area AA. After the formation of the hole injection and transport layer 141, the edge of the hole injection and transport layer 141 does not overlap with the second connection electrode 121 in the non-display area NA, and thus the exposed state of the second connection electrode 121 is maintained. In addition, the hole injection and transport layer 141 also does not overlap with the first connection electrode 122 positioned outside the second connection electrode 121 after the formation of the hole injection and transport layer 141.

Then, the first emission layers 152, 151, and 153 of the sub-pixels G_SP, B_SP, and R_SP are formed on the hole injection and transport layer 141.

The first emission layers 152, 151, and 153 are respectively provided in the sub-pixels G_SP, B_SP, and R_SP, and may be formed using a fine metal mask (FMM) having fine openings. Further, the emission layer 152 provided in the green sub-pixel G_SP may be a green emission layer emitting green light, the emission layer 151 may be a blue emission layer emitting blue light, and the emission layer 153 may be a red emission layer emitting red light. The green emission layer 152 may emit light with a peak wavelength of 510 nm to 590 nm, the blue emission layer 151 may emit light with a peak wavelength of 420 nm to 490 nm, and the red emission layer 153 may emit light with a peak wavelength of 600 nm to 650 nm.

As illustrated in FIG. 7E, the charge transport and generation layer 143 is formed on the first emission layers 152, 151, and 153 in the entire display area AA and extends to a part of the non-display area NA. The charge transport and generation layer 143 may include the first electron transport layer ETL1, the charge generation layer CGL, and the second hole transport layer HTL2, and the charge generation layer CGL may be positioned outside the first electron transport layer ETL1 and the second hole transport layer HTL2 in the non-display area NA and connected to the second connection electrode 121 while overlapping with the second connection electrode 121. In this case, the first electron transport layer ETL1 and the second hole transport layer HTL2 may have edges close to the edge of the hole injection and transport layer 141 and do not overlap with the second connection electrode 121.

Next, the second emission layers 162, 161, and 163 are formed on the charge transport and generation layer 143 to correspond to the sub-pixels G_SP, B_SP, and R_SP.

The second emission layers 162, 161, and 163 are respectively provided in the sub-pixels G_SP, B_SP, and R_SP, and may be formed using a fine metal mask (FMM) having fine openings. The emission layer 162 provided in the green sub-pixel G_SP may be a green emission layer emitting green light, the emission layer 161 may be a blue emission layer emitting blue light, and the emission layer 163 may be a red emission layer emitting red light.

Subsequently, the electron transport and injection layer 145 is formed in the entire display area AA and a part of the non-display area NA such that it has an edge ETL2_EG outside the edge CGL_EG of the charge generation layer. Here, the electron transport and injection layer 145 is formed inside the first connection electrode 122 such that the first connection electrode 122 is exposed even after the electron transport and injection layer 145 is formed.

As illustrated in FIG. 7F, the second electrode 170 is formed to extend to the non-display area NA to overlap with the entire display area AA and the first connection electrode 122. The first connection electrode 122 exposed is connected to the second electrode 170 during this process.

Next, light emitting display devices according to other aspects will be described.

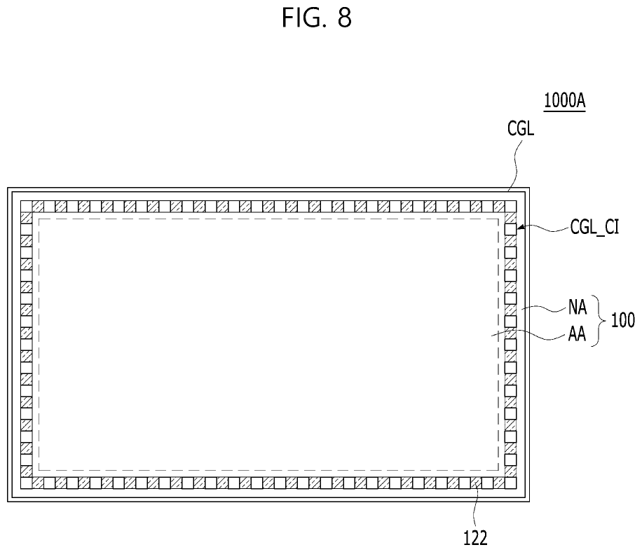

FIG. 8 is a plan view illustrating a light emitting display device according to a second aspect of the present disclosure.

As illustrated in FIG. 8, the light emitting display device 1000A according to the second aspect of the present disclosure includes a charge generation layer CGL and a plurality of island-shape charge generation layer connection regions CGL_CI in an area where the second connection electrode (shown as 121 in FIG. 2) is located on the substrate 100. In this case, since the second connection electrode 121 is located in the non-display area NA, the charge generation layer connection regions CGL_CI are located in the non-display area NA outside the display area AA.

The second connection electrode 121 and the charge generation layer CGL may have connection regions in a line along each side of the substrate.

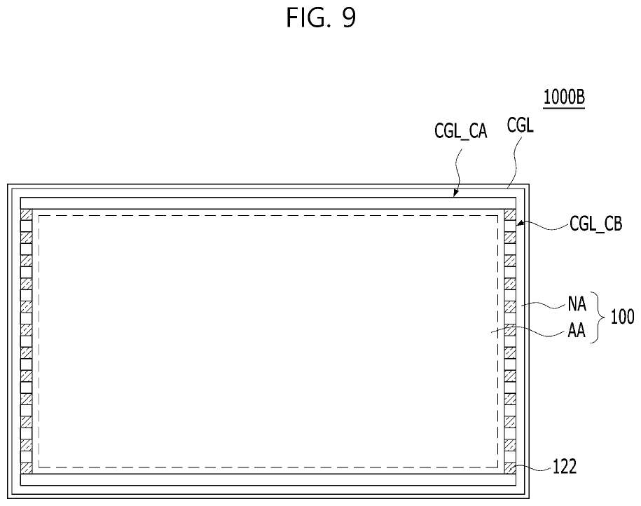

FIG. 9 is a plan view illustrating a light emitting display device according to a third aspect of the present disclosure.

As illustrated in FIG. 9, the light emitting display device 1000B according to the third aspect of the present disclosure includes linear connection regions CGL_CA and island-shape connection regions CGL_CB between the charge generation layer CGL and the second connection electrode 121 in the non-display area NA on the substrate 100.

In this case, the connection regions CGL_CA and CGL_CB correspond to regions where the charge generation layer CGL and the second connection electrode 121 overlap with each other, and the second connection electrode 121 may be omitted in the connection regions CGL_CA and CGL_CB.

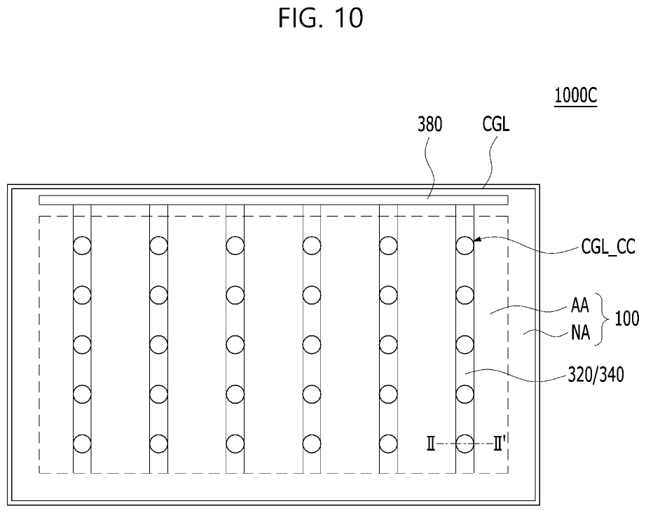

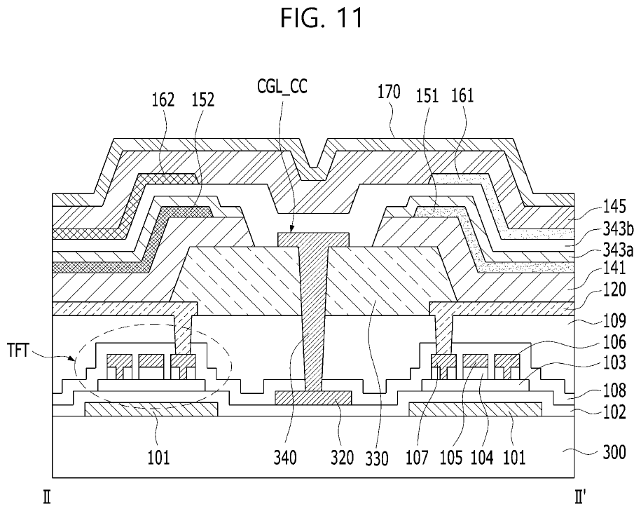

FIG. 10 is a plan view illustrating a light emitting display device according to a fourth aspect of the present disclosure, and FIG. 11 is a cross-sectional view taken along lines II-II′ of FIG. 10.

In the fourth aspect of the light emitting display device of the present disclosure, the reset voltage may be applied to the charge generation layer inside the display area AA according to circumstances.

As illustrated in FIGS. 10 and 11, a plurality of reset voltage lines 320 through which the reset voltage may be provided to be spaced apart from each other in the display device AA. Further, the reset voltage lines 320 may be connected to a power supply 380 supplying the reset voltage in the non-display area. The reset voltage lines 320 may overlap with a bank 330.

The reset voltage lines 320 may be connected to a second connection electrode 340, and the second connection electrode 340 may be directly connected to a charge generation layer 343b. A plurality of second connection electrodes 340 may be provided to be spaced apart from each other having a shape similar to the reset voltage lines 320 in the display area AA and overlaps with the reset voltage lines 320.

An upper portion of the second connection electrode 340 may be exposed from the upper surface of the bank 330 in the display area AA, and a lower portion of the second connection electrode 340 may penetrate the bank 330 to be connected to the reset voltage lines 320.

For example, a charge transport and generation layer provided between the first emission layers 152, 151, and 153 and the second emission layers 162, 161, and 163 may include a first electron transport layer 343a and a charge generation layer 343b. Here, the charge generation layer 343b may be formed by laminating an n-type charge generation layer and a p-type charge generation layer, and the lower surface of the n-type charge generation layer directly contacts the exposed second connection electrode 340 such that a reset signal may be supplied to the charge generation layer 343b. The p-type charge generation layer located on the upper side in the structure of the charge generation layer 343b including the laminated n-type charge generation layer and p-type charge generation layer may serve as a hole transport layer of the upper stack (or second stack). In this case, the second emission layers 162, 161, and 163 may be directly formed on the charge generation layer 343b without providing an additional common layer on the charge generation layer 343b. In some cases, it is possible to further include a separate hole transport layer on the charge generation layer 343b, as illustrated in FIG. 4A.

The charge generation layer 343b contacts the top of the second connection electrode 340 penetrating the bank 330 on the top of the bank 330 in the display area AA and also contacts the top of the neighboring bank 330 of the second connection electrode 340. In addition, the charge generation layer 343b is also connected to the side surface of the hole injection and transport layer 141 and the side surface of the first electron transport layer 343a exposed around the second connection electrode 340. Further, the upper surface of the charge generation layer 343b contacts side surfaces of the layers 343, 141, and 343a, and contacts the lower surface of the electron transport and injection layer 145.

Since the second emission layers 162, 161, and 163 are formed using a fine metal mask, they may be formed such that they do not overlap with the second connection electrode 340. Accordingly, the upper surface of the charge generation layer 343b on the second connection electrode 340 may directly contact the electron transport and injection layer 145 formed after the second emission layers 162, 161, and 163. The electron transport and injection layer 145 is made of a component having low resistance for interfacial connection with the second electrode 170 in the interlayer OS, and even if it is provided on the charge generation layer 343b, the resistances of the second connection electrode 340 and the charge generation layer 343b do not increase. In addition, the potential of the charge generation layer 343b is reset when the reset voltage signal is directly applied to the charge generation layer 343b through the second connection electrode 340, and thus the node of the charge generation layer 343b is initialized without charge accumulation. Accordingly, it is possible to prevent lateral leakage current due to the charge generation layer 343b.

In addition, as illustrated in FIGS. 5 and 6, when the potential of the charge generation layer 343b is reset, the node n1 of the lower hole injection layer connected in series with the charge generation layer 343b may also be reset, and thus lateral light leakage caused by leakage current due to another common layer or functional layer having high mobility in the light emitting element may be prevented.

Further, the reset voltage lines 320 may be formed on the same layer as the source electrode 106 and the drain electrode 107 of the thin film transistor, but the present disclosure is not limited thereto. The reset voltage lines 310 may be formed on the same layer as the light shielding layer 101 or, if the thin film transistor includes a heterogeneous thin film transistor, may be formed on the same layer as any one electrode.

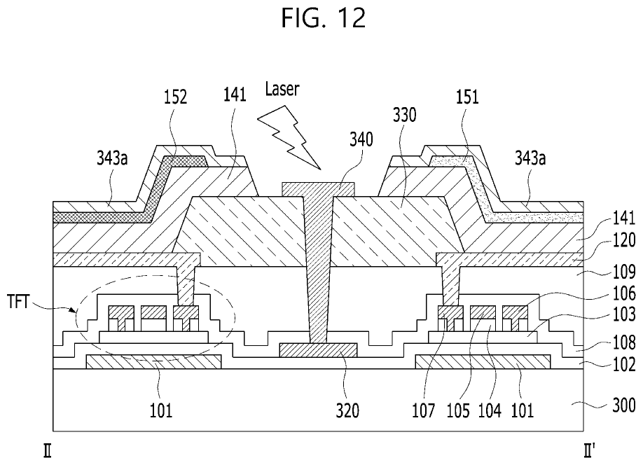

FIG. 12 is a cross-sectional view illustrating a method of exposing a common layer connection electrode in the light emitting display device according to the fourth aspect.

As illustrated in FIG. 12, the second connection electrode 340 may be exposed by radiating a laser to the upper portion of the second connection electrode 340 after formation of the first electron transport layer 343a to remove portions of the hole injection and transport layer 141 and the first electron transport layer 343a, which correspond to the laser radiation portion. According to laser radiation, the common layers 141 and 343a may be removed only in a local area of the bank 330 where the second connection electrode 340 is located. In the display area AA, the common layers 141 and 343a are removed in the shape of holes such as connection regions CGL_CC illustrated in FIG. 10, remaining portions of the common layers 141 and 343a that are not removed are normally formed, and thus a signal is transmitted to the common layers in an indirect manner in areas other than regions where the second connection electrode 340 is connected.

In addition, as illustrated in FIG. 11, the charge generation layer 343b formed on the second connection electrode 340 is connected to the second connection electrode 340 to periodically receive the reset signal, and thus the node potential of the charge generation layer 343b formed in the display area AA may be periodically reset. Accordingly, the light emitting display device according to the fourth aspect of the present disclosure may prevent abnormal operation due to lateral leakage current in adjacent sub-pixels, caused by charge accumulation in the charge generation layer 343b.

In the light emitting display device of the present disclosure, when the connection electrode is provided in the display area, the light emitting parts of the display area may not be affected by overlapping of the connection electrode with the bank.

Hereinafter, a light emitting display device according to a fifth aspect of the present disclosure will be described.

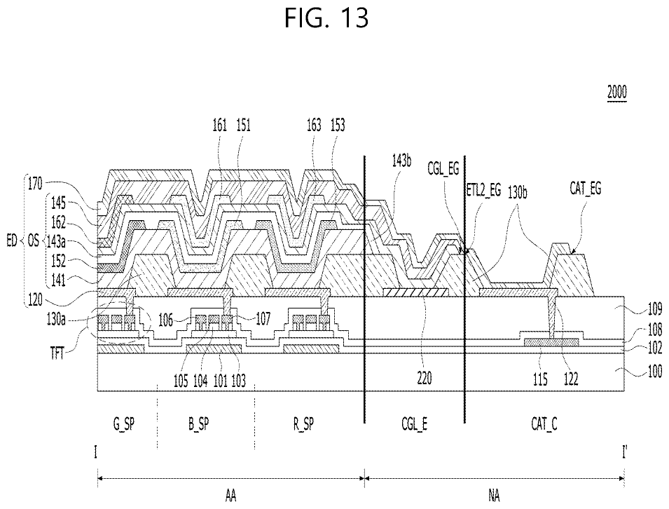

FIG. 13 is a cross-sectional view of the light emitting display device according to the fifth aspect of the present disclosure.

The light emitting display device according to the fifth aspect of the present disclosure illustrated in FIG. 13 includes the charge generation layer 143b connected to the second connection electrode 220 as in the above-described aspects, but differs therefrom in that the reset voltage is not supplied to the second connection electrode 220.

In this case, the charge generation layer 143b also includes metal ions such as alkali ions, alkaline earth metals, and transition metals. Therefore, when the charge generation layer 143b is disposed on the outer side in the interlayer OS, the metal ions may capture moisture, and thus moisture permeation and outside air permeation into the display area AA may be prevented.

In this case, the hole generation layer of the upper stack on the charge generation layer 143b on the second connection electrode 220 in the non-display area NA may be omitted, and the p-type charge generation layer of the charge generation layer 143b may serve as the hole generation layer.

Although the above description focuses on the charge generation layer CGL and the connection electrode, the light emitting display device of the present disclosure is not limited thereto. If there is a common layer that has high mobility and causes lateral leakage current, the common layer is connected to the second connection electrode located in the non-display area or the second connection electrode in the display area, and the reset voltage is supplied thereto to prevent charge accumulation in the common layer and prevent lateral leakage current. For example, layers having large leakage current, such as the hole injection layer or the hole transport layer, in addition to the charge generation layer, may be connected to the second connection electrode.

In the light emitting display device of the present disclosure, when the charge generation layer CGL or a common layer having high mobility is connected to the connection electrode in the display area, the stack between the connection electrode and the charge generation layer or the common layer having high mobility is removed through a removal process, and thus the surface of the connection electrode and the charge generation layer or the common layer having high mobility cab be directly connected. In addition, when the stack below the charge generation layer is removed, leakage current due to the lower stack may be structurally prevented.

The light emitting display device of the present disclosure has the following effects.

First, a connection electrode connected to a charge generation layer or a common layer having high mobility is provided, and thus the potential of the charge generation layer or the common layer having high mobility may be periodically reset through the connection electrode. The potential of the charge generation layer or the common layer having high mobility is reset, and thus charge accumulation in the node of the charge generation layer or the common layer having high mobility due to lateral leakage current may be prevented and generation of light leakage due to light emission of adjacent sub-pixels may be prevented.

Second, the connection electrode is formed of the same material on the same layer as the first electrode (i.e., anode), thereby ensuring material stability for light emitting elements. Accordingly, it is possible to prevent generation of harmful substances and prevent defects caused thereby. Therefore, it is possible to obtain ESG (environmental Social Governance) effects in terms of eco-friendliness, low power consumption, and process optimization.

Third, a charge generation layer or a common layer including metal ions in organic stacks of the interlayer has an edge in the non-display area outside other common layers and is connected to the connection electrode, and thus outside air or moisture permeation into the display area may be prevented by the metal ions.

Fourth, when the charge generation layer or the common layer having high mobility is connected to the connection electrode in the display area, stacks between the connection electrode and the charge generation layer or the common layer having high mobility are removed through a removal process, and thus the surface of the connection electrode may be directly connected to the charge generation layer or the common layer having high mobility. In addition, when a stack below the charge generation layer is removed, leakage current due to the lower stack may be structurally prevented.

Fifth, when the connection electrode is provided in the display area, light emitting parts of the display area are prevented from being affected by the connection electrode by overlapping the connection electrode with the bank.

A light emitting display device according to one or more aspects of the present disclosure may comprise a substrate including a display area having a plurality of sub-pixels and a non-display area surrounding the display area, a plurality of first electrodes at the plurality of sub-pixels, a second electrode facing the plurality of first electrodes over the entire display area and a part of the non-display area, an interlayer including a plurality of stacks between the plurality of first electrodes and the second electrode and a charge generation layer between the plurality of stacks, a first connection electrode at the non-display area and connected to the second electrode and a second connection electrode inside the first connection electrode and connected to the charge generation layer.

In a light emitting display device according to one or more aspects of the present disclosure, the charge generation layer may overlap with the second connection electrode, and an edge of the charge generation layer may be positioned between the second connection electrode and the first connection electrode.

In a light emitting display device according to one or more aspects of the present disclosure, the second connection electrode may be located at the non-display area inside the first connection electrode and has a closed loop shape. The second connection electrode and the charge generation layer may have a connection region in a closed loop shape corresponding to the shape of the second connection electrode.

In a light emitting display device according to one or more aspects of the present disclosure, the second connection electrode and the charge generation layer may have a connection region in a line along at least one side of the substrate.

In a light emitting display device according to one or more aspects of the present disclosure, the second connection electrode and the charge generation layer may have connection regions in a plurality of areas spaced apart from each other at least along the shape of the second connection electrode.

In a light emitting display device according to one or more aspects of the present disclosure, the second connection electrode may include a plurality of second connection electrodes spaced apart from each other and the plurality of second connection electrodes may be provided at the display area.

A light emitting display device according to one or more aspects of the present disclosure may further comprise a bank exposing light emitting parts of the plurality of first electrodes. The plurality of second connection electrodes may penetrate the bank.

In a light emitting display device according to one or more aspects of the present disclosure, each of the plurality of stacks may include a hole transport layer, an emission layer, and an electron transport layer. An edge of the electron transport layer may correspond to or may be positioned outside an edge of the hole transport layer.

In a light emitting display device according to one or more aspects of the present disclosure, the emission layers of the plurality of stacks may emit the same color in at least one of the plurality of sub-pixels.

In a light emitting display device according to one or more aspects of the present disclosure, the charge generation layer, an electron transport layer of an upper stack of the charge generation layer, and the second electrode may be sequentially stacked on the second connection electrode.

In a light emitting display device according to one or more aspects of the present disclosure, the plurality of sub-pixels may include first to third sub-pixels adjacent to each other. The first sub-pixel may include a first color emission layer in each of the plurality of stacks with the charge generation layer interposed between the stacks. The second sub-pixel may include a second color emission layer in each of the plurality of stacks with the charge generation layer interposed between the stacks. The third sub-pixel may include a third color emission layer in each of the plurality of stacks with the charge generation layer interposed between the stacks.

In a light emitting display device according to one or more aspects of the present disclosure, the first connection electrode may be connected to a power line through which a low-potential voltage is supplied, and the second connection electrode may be connected to a reset voltage line through which a reset voltage is supplied.

In a light emitting display device according to one or more aspects of the present disclosure, the second connection electrode may be positioned on the same layer as the plurality of first electrodes.

In a light emitting display device according to one or more aspects of the present disclosure, the second connection electrode may be positioned on a different layer from the plurality of first electrodes.

A light emitting display device according to one or more aspects of the present disclosure may comprise a substrate including a display area having a plurality of sub-pixels and a non-display area surrounding the display area, a plurality of first electrodes at the plurality of sub-pixels, a first stack including a first common layer, a first emission layer, and a second common layer on the plurality of first electrodes, a third common layer on the first stack, a second stack including a fourth common layer, a second emission layer, and a fifth common layer on the third common layer, a second electrode provided on the second stack over the entire display area and a part of the non-display area, a first connection electrode on the same layer as the plurality of first electrodes at the non-display area and connected to the second electrode and a second connection electrode on the same layer as the plurality of first electrodes inside the first connection electrode and connected to at least one of the first common layer, the third common layer, and the fourth common layer.

In a light emitting display device according to one or more aspects of the present disclosure, the third common layer may include metal ions.

In a light emitting display device according to one or more aspects of the present disclosure, the plurality of sub-pixels may include first to third sub-pixels adjacent to each other. The first emission layer and the second emission layer of the first sub-pixel may include a first color emission layer emitting light of a first color, the first emission layer and the second emission layer of the second sub-pixel may include the second color emission layer emitting light of the second color, and the first emission layer and the second emission layer of the third sub-pixel may include the third color emission layer emitting light of the third color.

In a light emitting display device according to one or more aspects of the present disclosure, the first connection electrode may be connected to a power line through which a low-potential voltage is supplied, and the second connection electrode may be connected to a reset voltage line through which a reset voltage is supplied.

In a light emitting display device according to one or more aspects of the present disclosure, each of the first common layer and the fourth common layer may include a hole transport layer. Each of the second common layer and the fifth common layer may include an electron transport layer. The third common layer may include a charge generation layer.

In a light emitting display device according to one or more aspects of the present disclosure, the third common layer may overlap with the second connection electrode, and an edge of the third common layer may be positioned between the second connection electrode and the first connection electrode.

In a light emitting display device according to one or more aspects of the present disclosure, the second connection electrode may be positioned in the non-display area inside the second connection electrode and has a closed loop shape.

In a light emitting display device according to one or more aspects of the present disclosure, the second connection electrode may include a plurality of second connection electrodes spaced apart from each other and the plurality of second connection electrodes may be provided at the display area.

It will be apparent to those skilled in the art that various modifications and variations may be made in the present disclosure without departing from the spirit or scope of the disclosure. Thus, it is intended that the present disclosure cover the modifications and variations of this disclosure provided they come within the scope of the appended claims and their equivalents.

What is claimed is:

1. A light emitting display device comprising:
a substrate including a display area having a plurality of sub-pixels and a non-display area surrounding the display area;
a plurality of first electrodes disposed at the plurality of sub-pixels;
a second electrode facing the plurality of first electrodes over the display area and a part of the non-display area;
an interlayer including a plurality of stacks disposed between the plurality of first electrodes and the second electrode and a charge generation layer disposed between the plurality of stacks;
a first connection electrode disposed at the non-display area and connected to the second electrode; and
a second connection electrode disposed closer to the display area than the first connection electrode and connected to the charge generation layer.

2. The light emitting display device of claim 1, wherein the charge generation layer overlaps with the second connection electrode, and an edge of the charge generation layer is positioned between the second connection electrode and the first connection electrode.

3. The light emitting display device of claim 1, wherein the second connection electrode has a closed loop shape, and
wherein the second connection electrode and the charge generation layer have a connection region in the closed loop shape corresponding to a shape of the second connection electrode.

4. The light emitting display device of claim 1, wherein the second connection electrode and the charge generation layer have a connection region in a line along at least one side of the substrate.

5. The light emitting display device of claim 3, wherein the second connection electrode and the charge generation layer have connection regions in a plurality of areas spaced apart from each other at least along the shape of the second connection electrode.

6. The light emitting display device of claim 1, wherein the second connection electrode includes a plurality of second connection electrodes spaced apart from each other and the plurality of second connection electrodes are provided at the display area.

7. The light emitting display device of claim 6, further comprising a bank exposing light emitting parts of the plurality of first electrodes,
wherein the plurality of second connection electrodes penetrate the bank.

8. The light emitting display device of claim 2, wherein each of the plurality of stacks includes a hole transport layer, an emission layer, and an electron transport layer, and
wherein an edge of the electron transport layer corresponds to or is positioned outside an edge of the hole transport layer.

9. The light emitting display device of claim 8, wherein the emission layers of the plurality of stacks emit a same color as at least one of the plurality of sub-pixels.

10. The light emitting display device of claim 8, wherein the charge generation layer, an electron transport layer of an upper stack of the charge generation layer, and the second electrode are sequentially stacked on the second connection electrode.

11. The light emitting display device of claim 1, wherein the plurality of sub-pixels includes first to third sub-pixels adjacent to each other,
the first sub-pixel includes a first color emission layer in each of the plurality of stacks with the charge generation layer interposed between the plurality of stacks,
the second sub-pixel includes a second color emission layer in each of the plurality of stacks with the charge generation layer interposed between the plurality of stacks, and
the third sub-pixel includes a third color emission layer in each of the plurality of stacks with the charge generation layer interposed between the plurality of stacks.

12. The light emitting display device of claim 1, wherein the first connection electrode is connected to a power line through which a low-potential voltage is supplied, and the second connection electrode is connected to a reset voltage line through which a reset voltage is supplied.

13. The light emitting display device of claim 1, wherein the second connection electrode is positioned on a same layer as the plurality of first electrodes.

14. The light emitting display device of claim 1, wherein the second connection electrode is positioned on a different layer from the plurality of first electrodes.

15. A light emitting display device comprising:
a substrate including a display area having a plurality of sub-pixels and a non-display area surrounding the display area;
a plurality of first electrodes disposed at the plurality of sub-pixels;
a first stack including a first common layer, a first emission layer, and a second common layer on the plurality of first electrodes;
a third common layer disposed on the first stack;
a second stack including a fourth common layer, a second emission layer, and a fifth common layer on the third common layer;
a second electrode provided on the second stack over the entire display area and a part of the non-display area;
a first connection electrode disposed on a same layer as the plurality of first electrodes at the non-display area and connected to the second electrode; and
a second connection electrode disposed on a same layer as the plurality of first electrodes disposed to closer to the display area than the first connection electrode and connected to at least one of the first common layer, the third common layer, and the fourth common layer.

16. The light emitting display device of claim 15, wherein the third common layer includes metal ions.

17. The light emitting display device of claim 15, wherein the plurality of sub-pixels includes first to third sub-pixels adjacent to each other,
the first emission layer and the second emission layer of the first sub-pixel include a first color emission layer emitting light of a first color,
the first emission layer and the second emission layer of the second sub-pixel include a second color emission layer emitting light of a second color, and
the first emission layer and the second emission layer of the third sub-pixel include a third color emission layer emitting light of a third color.

18. The light emitting display device of claim 15, wherein the first connection electrode is connected to a power line through which a low-potential voltage is supplied, and the second connection electrode is connected to a reset voltage line through which a reset voltage is supplied.

19. The light emitting display device of claim 15, wherein each of the first common layer and the fourth common layer includes a hole transport layer,
each of the second common layer and the fifth common layer includes an electron transport layer, and
the third common layer includes a charge generation layer.

20. The light emitting display device of claim 15, wherein the third common layer overlaps with the second connection electrode, and an edge of the third common layer is positioned between the second connection electrode and the first connection electrode.

21. The light emitting display device of claim 15, wherein the second connection electrode is positioned in the non-display area inside the second connection electrode and has a closed loop shape.

22. The light emitting display device of claim 15, wherein the second connection electrode includes a plurality of second connection electrodes spaced apart from each other and the plurality of second connection electrodes are provided at the display area.
